(19) United States
(12) Patent Application Publication
(10) Pub. No.: US 2025/0068393 A1
(43) Pub. Date: Feb. 27, 2025

(54) LOOKUP TABLE INDEXING AND RESULT ACCUMULATION

(71) Applicant: Micron Technology, Inc., Boise, ID (US)

(72) Inventors: Junxian Ding, Boise, ID (US); Xinyu Wu, Boise, ID (US)

(21) Appl. No.: 18/771,433

(22) Filed: Jul. 12, 2024

Related U.S. Application Data
(60) Provisional application No. 63/533,433, filed on Aug. 18, 2023.

(51) Int. Cl. G06F 7/544; G06F 7/501; G11C 16/08

(52) U.S. Cl. CPC G06F 7/5443; G06F 7/501; G11C 16/08

(57) ABSTRACT

A memory apparatus may include an array of memory cells, an adder, and control circuitry coupled to the array and to the adder. The control circuitry can cause data comprising a lookup table to be stored in the array, receive first signaling indicative of a first particular input to the machine learning model, and receive second signaling indicative of a second particular input to the machine learning model. The control circuitry can cause the first particular input to be indexed to a first particular result in the lookup table, cause the second particular input to be indexed to a second particular result in the lookup table, cause the adder to accumulate the first particular result and the second particular result into an output, and send third signaling indicative of the output.

### PRIORITY INFORMATION

This application claims the benefit of U.S. Provisional Application No. 63/533,433, filed on Aug. 18, 2023, the contents of which are incorporated herein by reference.

### TECHNICAL FIELD

The present disclosure relates generally to semiconductor memory and methods, and more particularly, to apparatuses, systems, and methods for lookup table indexing and result accumulation.

### BACKGROUND

Memory devices are typically provided as internal, semiconductor, integrated circuits in computers or other electronic systems. There are many different types of memory including volatile and non-volatile memory. Volatile memory can require power to maintain its data (e.g., host data, error data, etc.) and includes random access memory (RAM), dynamic random-access memory (DRAM), static random-access memory (SRAM), synchronous dynamic random-access memory (SDRAM), and thyristor random access memory (TRAM), among others. Non-volatile memory can provide persistent data by retaining stored data when not powered and can include NAND flash memory, NOR flash memory, and resistance variable memory such as phase change random access memory (PCRAM), resistive random-access memory (RRAM), and magnetoresistive random access memory (MRAM), such as spin torque transfer random access memory (STT RAM), among others.

Flash memory devices can include a charge storage structure, such as is included in floating gate flash devices and charge trap flash (CTF) devices, which may be utilized as non-volatile memory for a wide range of electronic applications. Flash memory devices may use a one-transistor memory cell that allows for high memory densities, high reliability, and low power consumption.

Memory cells in an array architecture can be programmed to a target state. For example, electric charge can be placed on or removed from the floating gate of a memory cell to put the cell into one of a number of data states. For example, a single level cell (SLC) can be programmed to one of two data states representing one of two units of data (e.g., 1 or 0). Multilevel memory cells (MLCs) can be programmed to one of more than two data states. For example, an MLC capable of storing two units of data can be programmed to one of four data states, an MLC capable of storing three units of data can be programmed to one of eight data states, and an MLC capable of storing four units of data can be programmed to one of sixteen data states. MLCs can allow the manufacture of higher density memories without increasing the number of memory cells since each cell can represent more than one unit of data (e.g., more than one bit). However, MLCs can present difficulties with respect to sensing operations as the ability to distinguish between adjacent data states may deteriorate over time and/or operation.

In many instances, the processing resources (e.g., processor and/or associated functional unit circuitry) may be external to the memory array, and data is accessed via a bus between the processing resources and the memory array to execute a set of instructions. Processing performance may be improved in a processor-in-memory (PIM) device, in which a processor may be implemented internally and/or near to a memory (e.g., directly on a same chip as the memory array). A PIM device may save time by reducing and/or eliminating external communications and may also conserve power.

### BRIEF DESCRIPTION OF THE DRAWINGS

The present disclosure will be understood more fully from the detailed description given below and from the accompanying drawings of various embodiments of the disclosure.

FIG. 1 illustrates a schematic diagram of a portion of a non-volatile memory array in accordance with a number of embodiments of the present disclosure.

FIG. 2 is a block diagram of an example memory apparatus including a memory device in accordance with some embodiments of the present disclosure.

FIG. 3 illustrates an example of a system including an array of memory cells, a column decoder, and an adder in accordance with some embodiments of the present disclosure.

FIG. 4 illustrates an example of a lookup table used in matrix multiplication in accordance with some embodiments of the present disclosure.

FIG. 5 illustrates an example method for lookup table indexing and result accumulation in accordance with some embodiments of the present disclosure.

FIG. 6 is a flow diagram of another example method for lookup table indexing and result accumulation in accordance with some embodiments of the present disclosure.

FIG. 7 is a block diagram of an example computing system that includes a memory sub-system in accordance with some embodiments of the present disclosure.

### DETAILED DESCRIPTION

Aspects of the present disclosure are directed to lookup table indexing and result accumulation. Utilizing a not- and (NAND)-based processor in memory (PIM) architecture, a matrix multiplication can be performed and integrated into the NAND memory device, which can reduce the amount of data transferred between the memory device and a processor. Put another way, the mathematical matrix multiplication calculation can be performed on the memory device, so data doesn't need to be moved from the PIM device.

A PIM device (e.g., bit vector operation NAND memory device) includes instructions including PIM commands (e.g., microcode instructions) sent to a memory device having PIM capabilities to implement logical operations. The PIM device may store the PIM commands within a memory array and can be executed by a controller on the memory device without having to transfer commands back and forth with a host over a bus. The PIM commands may be executed on the memory device to perform logical operations on the memory device that may be completed in less time and using less power than performing logical operation on the host. Additionally, time and power saving advantages may be realized by reducing the amount of data that is moved around a computing system to process the requested memory array operations (e.g., reads, writes, etc.).

A number of embodiments of the present disclosure can provide reduced or avoided weight matrix transferring between a memory device and a processing unit as occurs in Van Neumann Architectures, for example. Input/output (I/O) bandwidth needs can be reduced in a number of embodiments of the present disclosure, which may be a bottleneck of artificial intelligence and machine learning performance. Improved parallelism and/or reduced power consumption in association with performing compute functions can be achieved as compared to previous systems such as previous PIM systems and systems having an external processor (e.g., a processing resource located external from a memory array, such as on a separate integrated circuit chip).

For instance, a number of embodiments can provide for performing compute functions such as matrix multiplication with respect to a weight matrix associated with a machine learning model (MLM) without transferring the weight matrix out of the memory array and/or sensing circuitry via a bus (e.g., data bus, address bus, control bus). In addition, as the weight matrix can be programmed and stored in a memory device (e.g., NAND memory) and processed in the memory device, DRAM may not be needed to store temporary data, which can result in cost savings, as well as I/O power savings because the weight matrix need not be transferred from the memory device for processing. Further, because NAND memory, for instance, is a re-writable structure, the weight matrix programmed to the memory device may be updatable allowing for additional training of the weight matrix as compared to other approaches.

In previous approaches, data may be transferred from the array and sensing circuitry (e.g., via a bus comprising I/O lines) to a processing resource such as a processor, microprocessor, and/or compute engine, which may comprise ALU circuitry and/or other functional unit circuitry configured to perform the appropriate logical operations. However, transferring data from a memory array and sensing circuitry to such processing resource(s) can involve significant power consumption. Even if the processing resource is located on a same chip as the memory array, significant power can be consumed in moving data out of the array to the compute circuitry, which can involve performing a sense line (which may be referred to herein as a digit line or data line) address access (e.g., firing of a column decode signal) in order to transfer data from sense lines onto I/O lines (e.g., local I/O lines), moving the data to the array periphery, and providing the data to the compute function.

Aspects of the present disclosure address the above and other deficiencies by providing a memory sub-system including a PIM device for programming, storing, and processing a lookup table for matrix multiplication associated with operation of an MLM. This advantageously provides matrix multiplication processing integrated into a memory device (e.g., a NAND chip) such that much data movement can be avoided; for instance, a weight matrix need not be transferred between the memory device and a processor.

In some aspects, the examples described herein relate to a memory apparatus, including a non-volatile memory device, including an array of memory cells, an adder, and control circuitry coupled to the array and to the adder. The control circuitry can cause data including a lookup table to be stored in the array, receive first signaling indicative of a first particular input to the machine learning model, and receive second signaling indicative of a second particular input to the machine learning model. In some examples the lookup table includes results of dot products of weights and inputs for a trained machine learning model. The control circuitry can cause the first particular input to be indexed to a first particular result in the lookup table, cause the second particular input to be indexed to a second particular result in the lookup table, cause the adder to accumulate the first particular result and the second particular result into an output, and send third signaling indicative of the output.

In some instances, the examples described herein relate to a memory apparatus, including: a NAND array, an adder, and control circuitry coupled to the NAND array and to the adder. The control circuitry can cause data including a lookup table to be stored in the NAND array, receive signaling indicative of a particular input to the machine learning model, cause the particular input to be indexed to a particular result in the lookup table, cause data corresponding to the particular result to be transferred to the adder, and cause the adder to add individual elements of the particular result to yield an output; and send signaling indicative of the output.

In some aspects, the examples described herein relate to a method, including sensing and saving, utilizing a column decoder of a non-volatile memory device, a first input and a second input to a cache including a read-only, trained MLM. The method can include indexing, utilizing the column decoder, the first input only to a column of a first lookup table associated with the first input in response to receipt of the first input and indexing, utilizing the column decoder, the second input only to a column of a second lookup table associated with the second input in response to receipt of the second input. The first and the second lookup tables can include results of dot products of weights and inputs for the trained MLM. The method can include transferring results of the indexing of the first and the second input to an adder coupled to the non-volatile memory device, accumulating, utilizing the column decoder and an adder, individual elements of the results, and outputting the accumulation.

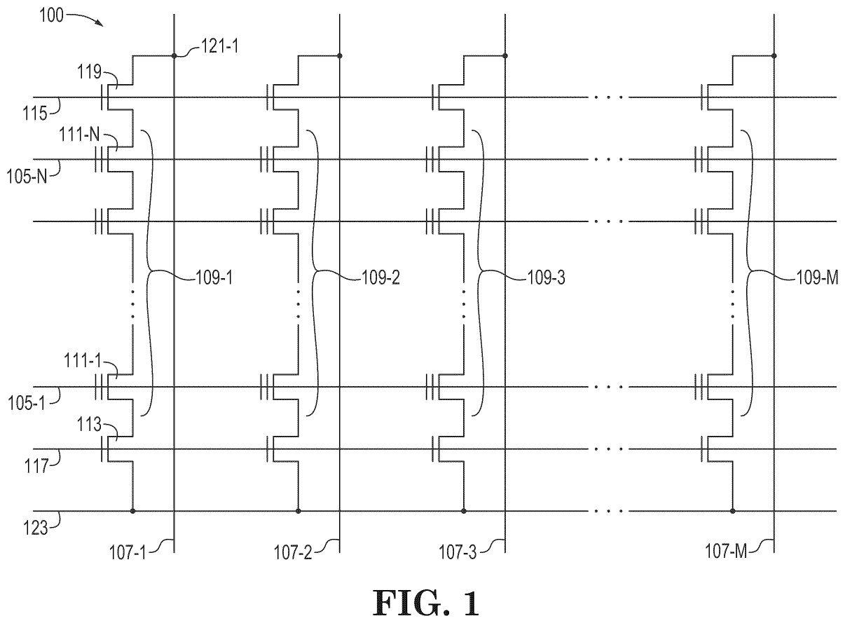

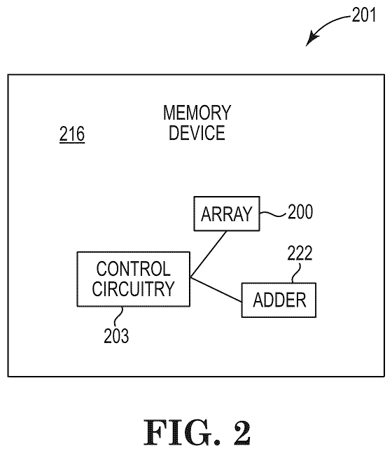

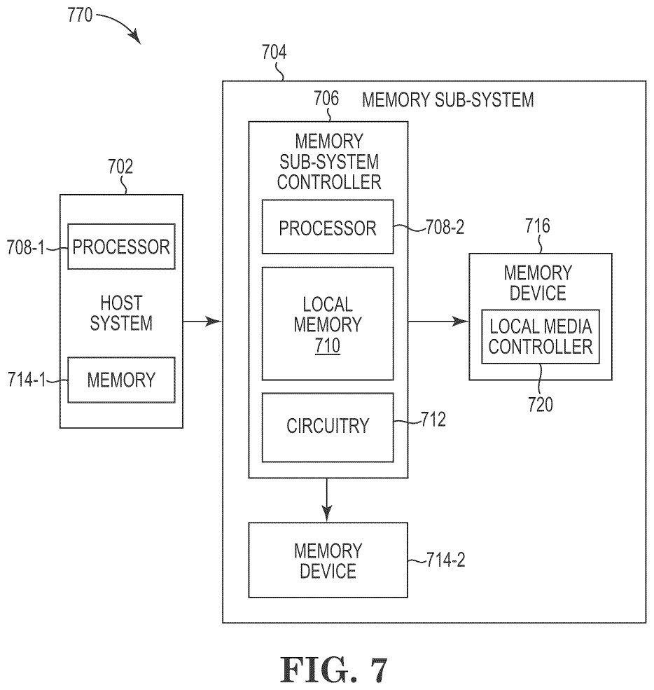

The figures herein follow a numbering convention in which the first digit or digits correspond to the drawing figure number and the remaining digits identify an element or component in the drawing. Similar elements or components between different figures may be identified by the use of similar digits. For example, 100 may reference element “00” in FIG. 1, and a similar element may be referenced as 200 in FIG. 2. Analogous elements within a Figure may be referenced with a hyphen and extra numeral or letter. Such analogous elements may be generally referenced without the hyphen and extra numeral or letter. For example, elements 708-1 and 708-2 in FIG. 7 may be collectively referenced as 708. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

FIG. 1 illustrates a schematic diagram of a portion of a non-volatile memory array in accordance with a number of embodiments of the present disclosure. The embodiment of FIG. 1 illustrates a NAND architecture non-volatile memory array. However, embodiments described herein are not limited to this example. As shown in FIG. 1, the memory array 100 includes access lines (e.g., word lines 105-1, . . . , 105-N) and intersecting data lines (e.g., local bit lines 107-1, 107-2, 107-3, . . . , 107-M). For ease of addressing in the digital environment, the number of word lines 105-1, . . . , 105-N and the number of local bit lines 107-1, 107-2, 107-3, . . . , 107-M can be some power of two (e.g., 256 word lines by 4,096 bit lines).

Memory array 100 includes NAND strings 109-1, 109-2, 109-3, . . . , 109-M. Each NAND string includes non-volatile memory cells 111-1, . . . , 111-N, each communicatively coupled to a respective word line 105-1, . . . , 105-N. Each NAND string (and its constituent memory cells) is also associated with a local bit line 107-1, 107-2, 107-3, . . . , 107-M. The memory cells 111-1, . . . , 111-N of each NAND string 109-1, 109-2, 109-3, . . . , 109-M are coupled in series source to drain between a source select gate (SGS) (e.g., a field-effect transistor (FET) 113) and a drain select gate (SGD) (e.g., FET 119). Each source select gate 113 is configured to selectively couple a respective NAND string to a common source 123 responsive to a signal on source select line 117, while each drain select gate 119 is configured to selectively couple a respective NAND string to a respective bit line responsive to a signal on drain select line 115.

As shown in the embodiment illustrated in FIG. 1, a source of source select gate 113 is coupled to a common source line 123. The drain of source select gate 113 is coupled to the source of the memory cell 111-1 of the corresponding NAND string 109-1. The drain of drain select gate 119 is coupled to bit line 107-1 of the corresponding NAND string 109-1 at drain contact 121-1. The source of drain select gate 119 is coupled to the drain of the last memory cell 111-N (e.g., a floating-gate transistor) of the corresponding NAND string 109-1.

In a number of embodiments, construction of the non-volatile memory cells 111-1, . . . , 111-N includes a source, a drain, a floating gate or other charge storage structure, and a control gate. The memory cells 111-1, . . . , 111-N have their control gates coupled to a word line, 105-1, . . . , 105-N, respectively. A NOR array architecture would be similarly laid out, except that the string of memory cells would be coupled in parallel between the select gates. Furthermore, a NOR architecture can provide for random access (e.g., sensing) to the memory cells in the array (e.g., as opposed to page-based access as with a NAND architecture).

A number (e.g., a subset or all) of cells coupled to a selected word line (e.g., 105-1, . . . , 105-N) can be programmed and/or sensed (e.g., read) together as a group. A number of cells programmed and/or sensed together can correspond to a page of data. In association with a sensing operation, a number of cells coupled to a particular word line and programmed together to respective charge storage states can be referred to as a target page. A programming operation (e.g., a write operation) can include applying a number of program pulses (e.g., 16V-20V) to a selected word line in order to increase the threshold voltage (Vt) of selected cells coupled to that selected access line to a desired program voltage level corresponding to a targeted charge storage state.

A sensing operation, such as a read or program verify operation, can include sensing a voltage and/or current change of a bit line coupled to a selected cell in order to determine the charge storage state of the selected cell. The sensing operation can include precharging a bit line and sensing the discharge when a selected cell begins to conduct. Two different types of sensing operations are described below (e.g., those using a ramping sensing signal versus using a plurality of discrete sensing signals).

Sensing the state of a selected cell can include providing a ramping sensing signal (e.g., −2V to +3V) to a selected word line, while providing a signal (e.g., a pass voltage such as 4.5V) to word lines coupled to the unselected cells of the string sufficient to place the unselected cells in a conducting state independent of the charge stored on the unselected cells. Alternatively, sensing the state of a selected cell could include applying discrete sensing voltages, e.g., −0.05V, 0.5V, and 2V, to a selected word line, and thus to the control gate of a selected cell. The bit line corresponding to the selected cell being read and/or verified can be sensed to determine whether or not the selected cell conducts in response to the particular sensing signal applied to the selected word line. For example, the charge storage state of a selected cell can be determined by the word line voltage at which the bit line current reaches a particular reference current associated with a particular state.

In some examples, the data comprising the lookup table can be stored in the array 100 such that results of dot products of the inputs for each weight are stored in a different access line. For instance, a first dot product may be stored in word line 105-1, and word line 105-N may store an Nth dot product. In some an access line decoder can be coupled to the array 100, and control circuitry can cause the access line decoder to select a particular access line corresponding to a desired weight to be selected to cause the particular input to be indexed to the particular result. For instance, when a dot product is desired, a corresponding word line 105 can be read.

FIG. 2 is a block diagram of an example memory apparatus 201 including a memory device 216 in accordance with some embodiments of the present disclosure. The memory device 216 can be a non-volatile PIM device and/or a non-volatile NAND memory device, for instance, and can include an array 200 of memory cells, a control circuitry 203, and an adder 222. The array 200 can be an array of single-level memory cells or multi-level cells, among others.

The array 200 can include a lookup table, as discussed further herein, which can be used to calculate and store a dot product of weights associated with the array of memory cells 200. For instance, the lookup table can include a dot product result for a plurality of weights received as integers. The memory device 216 and corresponding array 200 can include a plurality of lookup tables, and each one of the plurality of lookup tables can be read-only, with values in each one of the plurality of lookup tables being constant, allowing for increased transfer speeds reduced calculation times.

The memory device 216 can include a processor in some examples. By including the processor in memory, bandwidth limitation and I/O power limitations from data movement can be reduced. For instance, transferring data between a memory device and a processor in the memory device can result in less data movement and less I/O power consumption during transfer between the memory device/processing device and a host as compared to an external processing unit setup. Put another way, processing performance may be improved in a PIM device, in which a processor may be implemented internally and/or near to a memory (e.g., directly on a same chip as the memory array), which may conserve time and power in processing.

The control circuitry 203 can be coupled to the array 200 and the adder 222. In some examples, a processor may act as the control circuitry 203. Put another way, the processor may be a processor internal to the memory device 216, while a separate processor or memory controller may be a processor near the memory device 216.

The control circuitry 203 can cause data comprising a lookup table to be stored in the array 200. The lookup table can include results of dot products of weights and inputs for a trained MLM. The MLM may include a deep learning neural network MLM, which can include interconnected nodes or neurons in a layered structure that resembles the human brain. It can create an adaptive system that computing devices can use to learn from their mistakes and improve continuously. In a deep learning neural network MLM, data input and assigned weights can undergo matrix multiplication.

Information from the outside world can enter the artificial neural network from an input layer. Input nodes can process the data, analyze the data, and/or categorize the data, and pass it on to the next layer. Hidden layers can take their input from the input layer or other hidden layers. Artificial neural networks can have a plurality of hidden layers. Each hidden layer can analyze the output from the previous layer, process it further, and pass it on to the next layer. An output layer can give a final result of the data processing by the artificial neural network.

Deep learning neural networks may have a plurality of hidden layers with a plurality of artificial neurons linked together. The weight represents the connections between one node and another. The weight can be a positive number if one node excites another, or it can be a negative number if one node suppresses the other. Nodes with higher weight values have more influence on the other nodes.

In deep learning, raw data can be provided to software. The deep learning network can derive the features by itself and learn more independently as compared to other machine learning approaches. It can analyze unstructured datasets, identify which data attributes to prioritize, and solve more complex problems. In a deep learning neural network, matrix multiplication is a major calculation, but in a non-PIM device, this includes loading the weight into a processor to calculate dot products, and then transferring the information to the memory device. This can reduce transfer speeds as compared to a PIM device that allows for matrix multiplication on the memory device, as provided herein.

In some examples, for instance when a NAND memory device is used, a read operation may be faster than a write operation. In such examples, the calculation can occur during an inference phase of machine learning rather than a training phase. For example, in the case of an inference phase, the weight matrices can be trained, and all the values can be constant. Thus, the values (e.g., u, v, w, x, y, z as described further herein), can be stored as read-only. In addition, the deep learning neural network MLM can be stored as read-only on the memory device 216.

In some examples, the control circuitry 203 can receive first signaling indicative of a first particular input to the MLM, and the control circuitry 203 can receive second signaling indicative of a second particular input to the MLM. The first and the second particular inputs, for example, can be input matrices received as integers.

The control circuitry 203 can cause the first particular input to be indexed to a first particular result in the lookup table, the control circuitry 203 can cause the second particular input to be indexed to a second particular result in the lookup table. Put another way, the control circuitry 203 can cause data comprising a lookup table to be stored in the array 200. The lookup table, in some examples, can include a dot product lookup table which can include results of dot products of weights and inputs for a trained MLM. For instance, a dot product of a matrix can be a linear algebra computation used in deep learning models (e.g., deep learning MLMs) to complete operations with larger amounts of data. The dot product is the result of multiplying two matrices that have matching rows and columns, such as a 3×2 matrix and a 2×3 matrix.

In some examples, the data comprising the lookup table can be stored in the array 200 such that results of dot products of the inputs for each weight are stored in a different access line. The apparatus 201, in some examples, can include an access line decoder coupled to the array 200, and the control circuitry 203 can cause the access line decoder to select a particular access line corresponding to a desired weight to be selected to cause the particular input to be indexed to the particular result.

A column decoder, in some examples, may also be coupled to the array 200 and can be used to select at least one column for input/output of data. For instance, the column decoder can receive input values for sending to lookup tables of the memory device 216. The column decoder, for instance, can select only those columns associated with the first particular input in response to receipt of the first particular input and select only those columns associated with the second particular input in response to receipt of the second particular input. The control circuitry 203 can cause the particular input to be sent to the column decoder to cause the particular input to be indexed to a particular result in the lookup table. In some examples, the control circuitry can cause host data to be stored in the NAND array, cause a page of the host data to be read from the NAND array in response to receipt of a request for the page of host data, and cause the column decoder to select all columns for the request for the page of host data.

The control circuitry 203, in some examples, can cause data corresponding to a particular result (e.g., the first and/or the second particular result) to be transferred to the adder 222. The adder 222 can be caused (e.g., by the control circuitry 203) to add individual elements of the particular result to yield an output. For instance, the control circuitry 203 can cause the adder 222 to accumulate the first particular result and the second particular result into an output. Put another way, the adder 222 can be coupled to the array 200 and can perform matrix addition on the first and the second particular results. Matrix addition is the operation of adding two matrices by adding the corresponding entries together. The control circuitry 203 can send signaling (e.g., third signaling) indicative of the output (e.g., the results) to a host device, for instance.

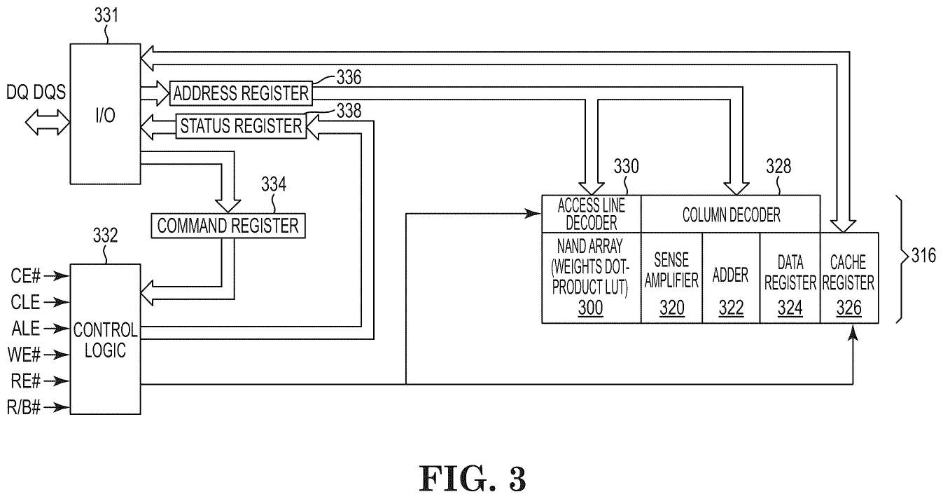

FIG. 3 illustrates an example of a NAND system including an array 300 of memory cells, a column decoder 328, and an adder 322 in accordance with some embodiments of the present disclosure. The example illustrated in FIG. 3 includes control signals, such as command latch enable (CLE), command enable (CE #), address latch enable (ALE), write enable (WE #), read enable (RE #), and/or ready/busy (R/B #) that can be received at control logic 332. The input/output (I/O) 331 can receive data via an 8-bit bidirectional data btus (DQ) and/or a bidirectional data strobe signal (DQS), among other examples. A status register 338 can store the current ready/busy state of the I/O 331 and/or memory device 316.

An access line address can be received at the access line decoder 330, which can activate an access line corresponding to the address for reading the access line. Signals corresponding to the data read from the access line can be sensed by a sense amplifier 320, and the column decoder 328 can be used to select and save data to a data register 324 for normal read operations. However, unlike some previous approaches, the memory device 316 includes an adder 322, which can optionally be used to add results of various read operations as described in more detail herein (e.g., to add results of dot products in order to complete a matrix multiplication operation). For normal read operations, the data register 324, can receive data related to a read command sent to the command register 334 from a host (e.g., via the I/O 331) and transfer the data to the cache register 326. The cache register 326 can output the data to the I/O 331, with the control logic 332 controlling the process. For operations that include operation of the adder 322, the data register can receive the results of the addition performed by the adder 322 (e.g., adding two dot products stored in different access lines) and transfer that data to the cache register 326 to be output to the I/O 331.

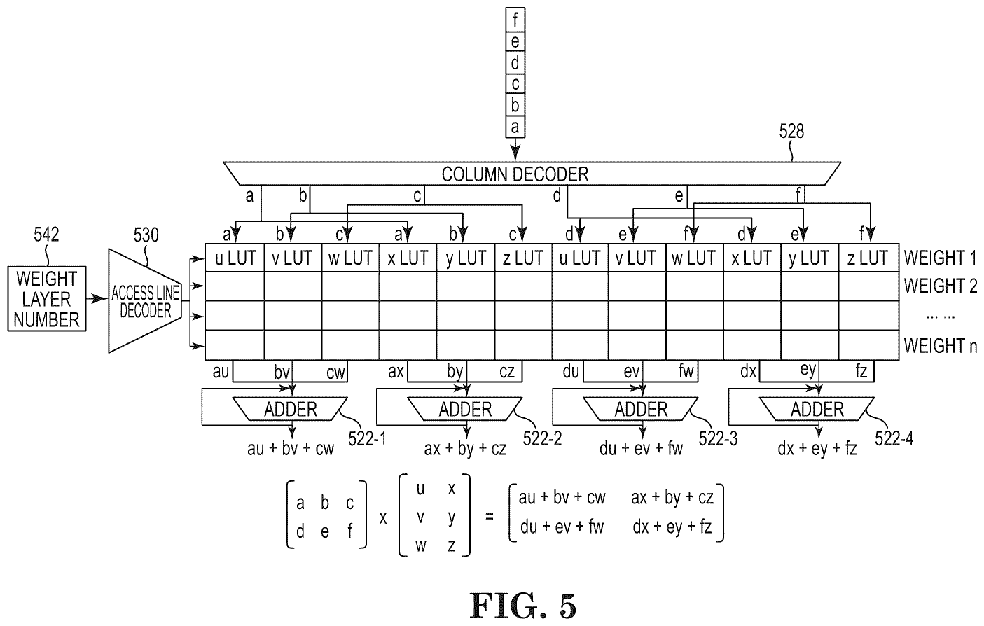

In the example illustrated in FIG. 3, the array 300 (e.g., a NAND array) can include single-level memory cells and/or multi-level memory cells, among other memory cell types. The array 300 can include (e.g., save) a saved dot product lookup table or a plurality of saved dot product lookup tables. A dot product lookup table can include a dot product result of a plurality of inputs and a plurality of weights (inputs-weights). In some instances, the inputs (e.g., “a”, “b”, “c”, “d”, “e”, “f” as illustrated in FIG. 5) and/or weights (e.g., “u”, “v”, “w”, “x”, “z” as illustrated in FIG. 5) can be received from the host as integers, rather than as floating points. The MLM can be trained, so the weights (e.g., weight matrices) are constant. Therefore, the weights can be stored as read only values. Because the lookup tables (e.g., weight matrix lookup tables) stored in the array 300 include the result of multiplying the inputs and the weights, only the inputs are needed to be received from the host. The input (multiplier) can be indexed to the lookup table to find the resultant dot product, which can be read from the lookup table. Signals indicative of the corresponding data can be sensed from a respective access line of the memory array 300 by the sense amplifier 320. Data read from multiple access lines can be added by the adder 322, thereby completing the matrix multiplication operation. The data can be received by the data register 324 from the adder 322 and send to the cache register 326 as described above. The lookup table or tables, in some examples, can be read-only, and the values in the lookup table or tables can be constant (e.g., where the MLM has been trained). The matrix multiplication operation is described in more detail below.

When matrix multiplication is desired, in some examples, the host device (e.g., via I/O 331) can send an access line address and a column address to the memory device 316 via address register 336 (e.g., received at access line decoder 330) to activate a corresponding access line. In some instances, a column address can be sent to the memory device 316 via address register 336 (e.g., received at column decoder 328). Data can also be received at the memory device 316 from the host via the cache register 326 and data register 324.

In some examples the memory device 316 can receive an input value to index the lookup table (e.g., in the array 300) and find a result of a dot product. The results of the dot product can be sent to the adder 322 which can complete the matrix multiplication function by adding the results of different dot products, and the result can be sent back to the host.

The memory device 316 can be a PIM device, and may include (e.g., internally and/or be coupled to) control circuitry to cause indexing of input received at the memory device 316 to a lookup table that stores results of dot products of various inputs with a trained weight matrix to be used in association with an MLM. The MLM, for instance, may be an inference model. The control circuitry can cause accumulation of the results of multiple dot products, utilizing the column decoder 328 and the adder 322. The result of the accumulation is analogous to the result of a matrix multiplication that would otherwise be performed by a host processor.

The following multiplication of an input matrix (“a” through “f”) and a weight matrix (“u” through “z”):

$$[ \begin{matrix}a & b & c \\ d & e & f\end{matrix} ] \times [ \begin{matrix}u & x \\ v & y \\ w & z\end{matrix} ]$$

is described as an example. In the matrix multiplication, “a” and “u” would be multiplied (dot product), then “b” and “v” multiplied (dot product), and then “c” and “w” multiplied (dot product). These three results (dot products) would be added together to get an output (e.g., “au+by +cw”). This multiplying and adding can continue for the remaining combinations. According to some previous approaches, such a matrix multiplication operation could be performed for a weight matrix stored in a memory device by reading the weight matrix out of the memory device and transferring it to a host device, and then multiplying the weight matrix by the input matrix via one or more processors of the host device. In contrast, at least one embodiment of the present disclosure includes storing the results of the individual dot product results for a given weight matrix and given inputs in a lookup table in the memory device 316 and then performing the addition thereof using an adder 322 integrated into the memory device 316.

In the example illustrated in FIG. 3, a lookup table can be located in (e.g., stored in) the NAND array 300. The aforementioned output can be constant values (e.g., “au+by +cw” is a constant value), so the multiplication may not need to be calculated each time, rather the value can be looked up in the lookup table of the NAND array 300. Put another way, because the input values may be limited, the lookup table can be limited in size, so any “a” value input can instantly have an “au” output value, without a multiplication operation being performed. Should the value of “a” change, the value of “au” changes, “au” can be recalculated, and the lookup table updated.

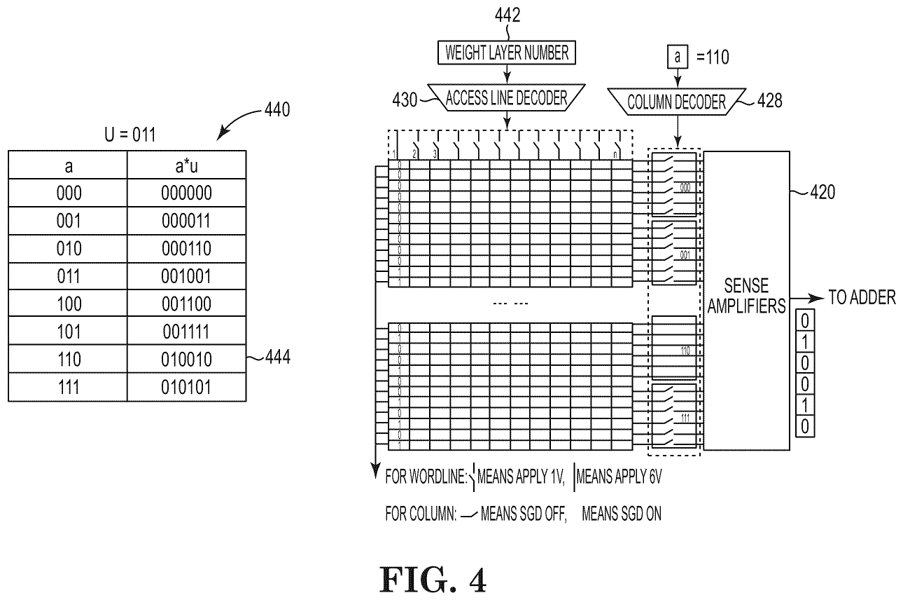

FIG. 4 illustrates an example of a lookup table 440 used in matrix multiplication in accordance with some embodiments of the present disclosure. The lookup table 440 illustrated in FIG. 4 includes 16 values: eight “a” values and eight “a*u” values, and in some examples may be a portion of a lookup table. The “a” values are inputs, the “u” values are weights, and the “a*u” values are possible dot product values stored in the array of memory cells. A lookup table or tables in accordance with the present disclosure may include more or fewer values, columns, rows, etc. As illustrated in FIG. 4, the access lines/word lines are vertical, and the columns/sense lines/data lines are horizontal. The access line decoder 430 is coupled to the vertically illustrated access lines. The column decoder 428 and sense amplifiers 420 are coupled to the horizontally illustrated sense lines.

In the example illustrated in FIG. 4, an “a” value can be received (e.g., at the column decoder 428), for example “a”=110. Only columns with a matching “a” value are active (e.g., opened) and allow data transfers to the sense amplifiers 420. The lookup table 440 with the stored “a*u” values allow for only “a” values needed at a host, and resulting applicable columns can be determined, saving transfer time and memory power consumption. Put another way, once an input value (e.g., “a” value) is received, a dot product can be pulled from the lookup table (e.g., value 010010 at 444). The input is indexed to the table such that the input indicates to the column decoder 428 which subset of sense lines to activate. In this example, the input “a=110” causes the column decoder 428 to select the sense lines indicated by the shading. The result is that the data stored in memory cells of word line 1 and coupled to the activated sense lines to be sensed by the sense amplifiers 420 and output to the adder. In this example, that data is “010010”.

An example matrix multiplication associated with the lookup table 440 may include:

TABLE 1
$[ \begin{matrix}a & b & c \\ d & e & f\end{matrix} ] \times [ \begin{matrix}u & x \\ v & y \\ w & z\end{matrix} ] = [ \begin{matrix}a u + bv + cw & ax + by + cz \\ du + ev + fw & dx + ey + fz\end{matrix} ]$

Because the weights are constant values, the lookup table of each of “u, v, w, x, y, z” can be precalculated. The lookup table of weight 1 can be stored in access line 1, the lookup table of weight 2 can be stored in access line 2, etc. In this example, the weight itself is the index to the access line. For example, weight u indexes to access line 1, indicating to the access line decoder 430 to select access line 1. In the example illustrated in FIG. 4, the lookup table 440 of “u” is shown, where the value of “a” is input to a column decoder 428, which can select a corresponding column by its value. Also, in the example illustrated in FIG. 4, the memory cells are NAND cells and are in an SLC mode, though examples are not limited to SLC mode.

An access line can be selected based on a weight layer number 442 utilizing the access line decoder 430. In the example illustrated in FIG. 4, access line 1 is selected. This is illustrated by the closed line above the worldline 1, which means 6 volts is to be applied. Following selection of the access line, columns corresponding to the “a” value (e.g., “a”=110 here) are selected, for instance using the column decoder 428. In the example illustrated in FIG. 4, the darker shaded columns are selected, as the columns correspond to the example “a” value of 110, as illustrated by the closed line to the right of the selected columns meaning the SGD is on. For instance, the lookup table 440 illustrates at 444 the “a*u” value associated with an “a” value of 110 is 010010, as illustrated in the darker shaded columns. The sense amplifiers 420 can output to the adder that a*u=110*011=0100100, as is illustrated to the right of the sense amplifiers 420 and at box 444 of the lookup table 440.

FIG. 5 illustrates an example method for matrix multiplication in accordance with some embodiments of the present disclosure. The matrix multiplication can utilize lookup tables (“LUT”) for each value from the matrices to be multiplied (e.g., see Table 1 above). For instance, lookup tables can include u LUT, v LUT, w LUT, . . . , z LUT, as illustrated in FIG. 5. At box 528, the column decoder can receive as input from a host, values associated with a first matrix (e.g., values “a”, “b”, “c”, “d”, “e”, “f”) and can assign each of those values to a lookup table. The input can be received at the column decoder from the host sequentially (e.g., “a” first, “b” second, etc.).

The “u” and “x” lookup tables can be used to retrieve “au” and “ax”, then “v” and “y” lookup tables can be used to retrieve “by” and “by”, and the method can continue until each result is determined. For instance, in the example illustrated in FIG. 5, six cycles would be needed to create an internal matrix multiplication lookup table (e.g., an internal grid). A number of cycles can vary depending on the size of the matrix.

At 542, an access line can be selected based on a weight layer number utilizing an access line decoder as illustrated at quadrilateral 530. In the example illustrated in FIG. 5, a lookup table of weight 1 is stored in access line 1, a lookup table of weight 2 is stored in access line 2, a lookup table of weight n is stored in access line n, etc.

In such an example, the input and output sequences may match a target MLM (e.g., target machine learning inference model). For instance, during an input cycle, a first column address is “a”, and the column decoder can use it to access “u” and “x” lookup tables, while a second column address is “b”, which can be used to access “v” and “y” lookup tables, and so on.

During an output cycle of the method illustrated in FIG. 5, the first result via an adder at 522-1 is “au+by +cw”, the second result via an adder at 522-2 is “ax+by +cz”, the third result via an adder at 522-3 is “du+ev+fw”, and the fourth result via an adder at 522-4 is “dx+ey+fz”.

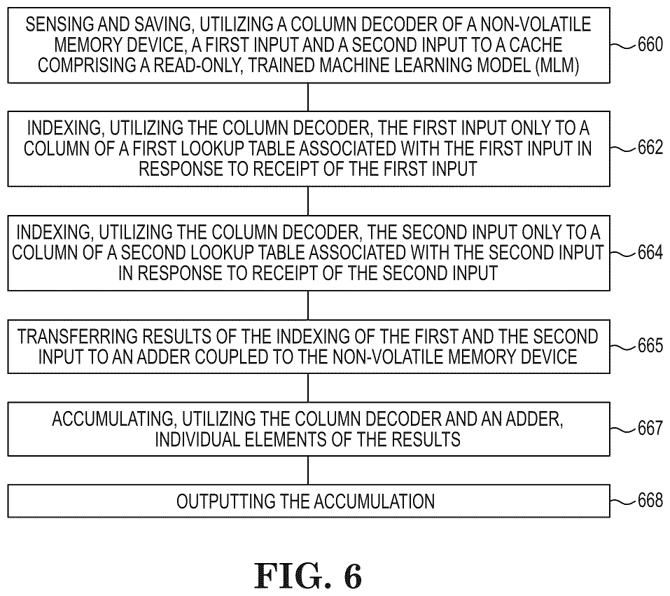

FIG. 6 is a flow diagram of another example method for matrix multiplication in accordance with some embodiments of the present disclosure. At block 660 in the example method of FIG. 6, a column decoder of a non-volatile memory device can be utilized to sense and save a first input (e.g., in integer form) and a second input (e.g., in integer form) to a cache comprising a read-only, trained MLM. The cache, for instance, can be a NAND memory device that includes a processor (e.g., a PIM device). For instance, during an input cycle, the first input can be received at a host (e.g., column address “a”), and the column decoder can use the first input to access different lookup tables (e.g., lookup tables “u” and “x”). The second input can be received at the host (e.g., column address “b”), and the column decoder can use the second input to access different lookup tables (e.g., lookup tables “v” and “y”). Put another way, the input cycle (e.g., send command, send address, send command, send address, memory device busy, send command, result) can be a data cycle, and the signals can be on a same bus. The host can send an access line address to the memory device to activate a corresponding access line.

At block 662 in the example method of FIG. 6, the first input can be indexed (e.g., utilizing the column decoder) only to a column of a first lookup table associated with the first input in response to receipt of the first input. At block 664, the second input can be indexed (e.g., utilizing the column decoder) only to a column of a second lookup table associated with the second input in response to receipt of the second input. The first and the second lookup tables can include, for instance, results of dot products of weights received as integers at the non-volatile memory device and inputs received as integers for the trained MLM.

As such, matrix multiplication need not be performed on the memory device. Rather, utilizing the read-only trained MLM (e.g., a deep learning inference MLM), a matrix multiplication result can be found for a plurality of inputs received at the non-volatile memory device using values from the lookup table. For instance, for each weight layer of the trained MHLM, each weight's dot product results can be pre-calculated into the lookup table, which can be stored to an access line of the memory device (e.g., a NAND access line). As the inputs are received at the host device, which then sends the input value to the memory device, the memory device and its internal processor can use the input value to index the lookup table and find a result of the dot product. For instance, the memory device can be a non-volatile NAND-based PIM device, and a processor within the NAND-based PIM device can be utilized to perform elements of the method of FIG. 6.

At block 665 in the example method of FIG. 6, results of the indexing of the first and the second input can be transferred to an adder coupled to the non-volatile memory device. At block 667, the column decoder and the adder can be used to accumulate individual elements of the results, and at block 668, the accumulation can be output. Put another way, the results can be accumulated utilizing the column decoder and the adder. The results of the dot product can be sent to the adder, the adder can complete an add function of the results, and the resulting accumulation can be sent back to the host.

Although not specifically illustrated, the method can include updating the MLM. For instance, the MLM can be stored as read-only to reduce the need to continuously find values. Because the weight is already defined and constant, the MLM and the lookup tables can be stored as read-only. However, if during training, it is determined the MLM is to be updated, the lookup tables can be updated, and the matrices may be updated to a new constant. These can again be stored as read-only following the update. Because the MLM does not change during an inference stage, the matrices and lookup tables do not need to be updated (and can be stored as read-only) unless the MLM needs to be updated.

FIG. 7 is a block diagram of an example computing system 770 that includes a memory sub-system 704 in accordance with some embodiments of the present disclosure. The memory sub-system 704 can include media, such as one or more volatile memory devices 714-2, one or more non-volatile memory devices 716, or a combination thereof. The volatile memory devices 714-1, 714-2 illustrated in FIG. 7 can be, but are not limited to, random access memory (RAM), such as dynamic random-access memory (DRAM), synchronous dynamic random access memory (SDRAM), and resistive DRAM (RDRAM). The memory sub-system 704 can also include additional circuitry or components that are not illustrated. In some embodiments, the memory sub-system 704 can include address circuitry (e.g., a row decoder and a column decoder) that can receive an address from the memory sub-system controller 706 and decode the address to access the non-volatile memory devices 716.

A memory sub-system 704 can be a storage device, a memory module, or a hybrid of a storage device and memory module. Examples of a storage device include an SSD, a flash drive, a universal serial bus (USB) flash drive, an embedded Multi-Media Controller (eMMC) drive, a Universal Flash Storage (UFS) drive, a secure digital (SD) card, and a hard disk drive (HDD). In at least one embodiment, the memory sub-system 704 is an automotive grade SSD. Examples of memory modules include a dual in-line memory module (DIMM), a small outline DIMM (SO-DIMM), and various types of non-volatile dual in-line memory module (NVDIMM).

The computing system 770 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 770 includes a host system 702 that is coupled to one or more memory sub-systems 704. In some embodiments, the host system 702 is coupled to different types of memory sub-systems 704. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 702 includes or is coupled to processing resources, memory resources, and network resources. As used herein, “resources” are physical or virtual components that have a finite availability within a computing system 770. For example, the processing resources include a processor 708-1 (or a number of processing devices), the memory resources include volatile memory 714-1 for primary storage, and the network resources include as a network interface (not specifically illustrated). The processor 708-1 can be one or more processor chipsets, which can execute a software stack. The processor 708-1 can include one or more cores, one or more caches, a memory controller (e.g., NVDIMM controller), and a storage protocol controller (e.g., PCIe controller, SATA controller, etc.). The host system 702 uses the memory sub-system 704, for example, to write data to the memory sub-system 704 and read data from the memory sub-system 704.

The host system 702 can be configured to provide virtualized or non-virtualized access to the memory sub-system 704 and/or the processing resources and network resources. Virtualization can include abstraction, pooling, and automation of the processing, memory, and/or network resources. To provide such virtualization, the host system 702 can incorporate a virtualization layer (e.g., hypervisor, virtual machine monitor, etc.) that can execute a number of virtual computing instances (VCIs). The virtualization layer 708 can provision the VCIs with processing resources and memory resources and can facilitate communication for the VCIs via the network interface. The virtualization layer represents an executed instance of software run by the host system 702. The term “virtual computing instance” covers a range of computing functionality. VCIs may include non-virtualized physical hosts, virtual machines (VMs), and/or containers. Containers can run on a host operating system without a hypervisor or separate operating system, such as a container that runs within Linux. A container can be provided by a virtual machine that includes a container virtualization layer (e.g., Docker). A VM refers generally to an isolated end user space instance, which can be executed within a virtualized environment. Other technologies aside from hardware virtualization can provide isolated application instances may also be referred to as VCIs. The term “VCI” covers these examples and combinations of different types of VCIs, among others.

The host system 702 can be coupled to the memory sub-system 704 via a physical host interface. Examples of a physical host interface include, but are not limited to, a serial advanced technology attachment (SATA) interface, a PCIe interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system 702 and the memory sub-system 704. The host system 702 can further utilize an NVM Express (NVMe) interface to access the non-volatile memory devices 716 when the memory sub-system 704 is coupled with the host system 702 by the PCIe interface. The physical host interface can provide an interface for passing control, address, data, and other signals between the memory sub-system 704 and the host system 702. In general, the host system 702 can access multiple memory sub-systems via a same communication connection, multiple separate communication connections, and/or a combination of communication connections.

The non-volatile memory devices 716 can be NAND type flash memory. NAND type flash memory includes, for example, two-dimensional NAND (2D NAND) and three-dimensional NAND (3D NAND). The non-volatile memory devices 716 can be other types of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, electrically erasable programmable read-only memory (EEPROM), and three-dimensional cross-point memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased.

Each of the non-volatile memory devices 716 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the non-volatile memory devices 716 can include one or more arrays of memory cells such as SLCs, MLCs, TLCs, QLCs, or any combination of such. In some embodiments, a particular memory device can include an SLC portion and an MLC portion, a TLC portion, a QLC portion, or a PLC portion of memory cells. The memory cells of the non-volatile memory devices 716 can be grouped as pages that can refer to a logical unit of the memory device used to store data. With some types of memory (e.g., NAND), pages can be grouped to form blocks.

The memory sub-system controller 706 (or controller 706 for simplicity) can communicate with the non-volatile memory devices 716 to perform operations such as reading data, writing data, erasing data, and other such operations at the non-volatile memory devices 716. The memory sub-system controller 706 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 706 can be a microcontroller, special purpose logic circuitry (e.g., a field programmable gate array (FPGA), an application specific integrated circuit (ASIC), etc.), or other suitable circuitry. In some examples, the memory device 716 may be a PIM device, and the memory sub-system controller may be located on the memory device 716.

The memory sub-system controller 706 can include a processor 708-2 configured to execute instructions stored in local memory 710. The local memory 710 of the memory sub-system controller 706 can be an embedded memory configured to store instructions for performing various processes, operations, logic flows, and routines that control operation of the memory sub-system 704, including handling communications between the memory sub-system 704 and the host system 702. The local memory 710 can be volatile memory, such as static random-access memory (SRAM).

In some embodiments, the local memory 710 can include memory registers storing memory pointers, fetched data, etc. The local memory 710 can also include ROM for storing micro-code, for example. While the example memory sub-system 704 has been illustrated as including the memory sub-system controller 706, in another embodiment of the present disclosure, a memory sub-system 704 does not include a memory sub-system controller 706, and can instead rely upon external control (e.g., provided by an external host, or by a processor or controller separate from the memory sub-system 704).

In general, the memory sub-system controller 706 can receive information or operations from the host system 702 and can convert the information or operations into instructions or appropriate information to achieve the desired access to the non-volatile memory devices 716 and/or the volatile memory devices 714. The memory sub-system controller 706 can be responsible for other operations such as media management operations (e.g., wear leveling operations, garbage collection operations, defragmentation operations, read refresh operations, etc.), error detection and/or correction operations, encryption operations, caching operations, and address translations between a logical address (e.g., logical block address) and a physical address (e.g., physical block address) associated with the non-volatile memory devices 716. The memory sub-system controller 706 can use error correction code (ECC) circuitry to provide the error correction and/or error detection functionality. The ECC circuitry can encode data by adding redundant bits to the data. The ECC circuitry can decode error encoded data by examining the ECC encoded data to check for any errors in the data. In general, the ECC circuitry can not only detect the error but also can correct a subset of the errors it is able to detect. The memory sub-system controller 706 can further include host interface circuitry to communicate with the host system 702 via the physical host interface. The host interface circuitry can convert a query received from the host system 702 into a command to access the non-volatile memory devices 716 and/or the volatile memory device 714-2 as well as convert responses associated with the non-volatile memory devices 716 and/or the volatile memory device 714-2 into information for the host system 702.

In some embodiments, the non-volatile memory devices 716 include a local media controller 720 that operates in conjunction with memory sub-system controller 706 to execute operations on one or more memory cells of the memory devices 716. An external controller (e.g., memory sub-system controller 706) can externally manage the non-volatile memory device 716 (e.g., perform media management operations on the memory device 716). In some embodiments, a memory device 716 is a managed memory device, which is a raw memory device combined with a local controller (e.g., local media controller 720) for media management within the same memory device package. An example of a managed memory device is a managed NAND device.

The host system 702 can send requests to the memory sub-system 704, for example, to store data in the memory sub-system 704 or to read data from the memory sub-system 704. The data to be written or read, as specified by a host request, is referred to as “host data.” A host request can include logical address information. The logical address information can be a logical block address (LBA), which may include or be accompanied by a partition number. The logical address information is the location the host system associates with the host data. The logical address information can be part of metadata for the host data. The LBA may also correspond (e.g., dynamically map) to a physical address, such as a physical block address (PBA), that indicates the physical location where the host data is stored in memory.

In some embodiments, the non-volatile memory device 716 can include integrated matrix multiplication processing (e.g., via circuitry 712) to reduce data movement (e.g., weight matrix transfer between the memory device(s) 710, 714, and/or 716 and the processor(s) 708). For a given trained MLM and for each of its weight layers, a dot-product can be pre-calculated into a lookup table, and then stored to an access line (e.g., a NAND access line). When a matrix multiplication is desired, the host system 702 can send the access line address to the memory device 716, which can use it to index the lookup table and find a dot product result. The result can be sent to an adder, which can complete an add function and send the result back to the host system 702.

Examples of the present disclosure can include a PIM device (e.g., PIM device 716). In order to appreciate the improved matrix multiplication techniques described herein, a discussion of an apparatus for implementing such techniques (e.g., a memory device having PIM capabilities) and associated host, follows. According to various embodiments, program instructions, (e.g., PIM commands) involving a memory device having PIM capabilities can distribute implementation of the PIM commands and/or constant data over multiple sensing circuitries that can implement logical operations and can store the PIM commands and/or constant data within the memory array, (e.g., without having to transfer such back and forth over an A/C and/or data bus between a host system 702 and the memory device). Thus, PIM commands and/or constant data for a memory device having PIM capabilities can be accessed and used in less time and using less power. For example, a time and power advantage can be realized by reducing the amount of data that is moved around a computing system to process the requested memory array operations (e.g., reads, writes, etc.).

A number of embodiments of the present disclosure can provide improved parallelism and/or reduced power consumption in association with performing compute functions as compared to previous systems such as previous PIM systems and systems having an external processor (e.g., a processing resource located external from a memory array, such as on a separate integrated circuit chip). For instance, a number of embodiments can include performing matrix multiplication on PIM device, such that transfer between a memory device and separate processor is not necessary.

The methods illustrated in FIG. 5 and FIG. 6 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method is performed by or using the apparatus 201 illustrated in FIG. 2, the memory sub-system 704, and/or the memory sub-system controller 706 shown in FIG. 7.

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

A set of instructions, for causing a machine to perform one or more of the methodologies discussed herein, can be executed. The instructions can be executed by a processing device (e.g., one or more general-purpose processing devices such as a microprocessor, a central processing unit, or the like). More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device can also be one or more special-purpose processing devices such as an ASIC, an FPGA, a digital signal processor (DSP), network processor, or the like. The processing device is configured to execute instructions for performing the operations and steps discussed herein. In some embodiments, the instructions can be communicated over a network interface device to communicate over a network.

A machine-readable storage medium (also known as a computer-readable medium) can store one or more sets of instructions or software embodying one or more of the methodologies or functions described herein. The instructions can also reside, completely or at least partially, within main memory and/or within a processing device during execution thereof by a computing system. The main memory and the processing device can also constitute machine-readable storage media.

The term “machine-readable storage medium” should be taken to include a single medium or multiple media that store the one or more sets of instructions. The term “machine-readable storage medium” should also be taken to include a medium that is capable of storing or encoding a set of instructions for execution by the machine and that cause the machine to perform one or more of the methodologies of the present disclosure. The term “machine-readable storage medium” should accordingly be taken to include, but not be limited to, solid-state memories, optical media, and magnetic media.

The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a machine-readable storage medium, such as, but not limited to, types of disks, semiconductor-based memory, magnetic or optical cards, or other types of media suitable for storing electronic instructions.

The present disclosure can be provided as a computer program product, or software, that can include a machine-readable medium having stored thereon instructions, which can be used to program a computer system (or other electronic devices) to perform a process according to the present disclosure. A machine-readable medium includes a mechanism for storing information in a form readable by a machine (e.g., a computer).

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

1. A memory apparatus, comprising:
a non-volatile memory device, comprising:
an array of memory cells;
an adder; and
control circuitry coupled to the array and to the adder, wherein the control circuitry is configured to:
cause data comprising a lookup table to be stored in the array, wherein the lookup table comprises results of dot products of weights and inputs for a trained machine learning model;
receive first signaling indicative of a first particular input to the machine learning model;
receive second signaling indicative of a second particular input to the machine learning model;
cause the first particular input to be indexed to a first particular result in the lookup table;
cause the second particular input to be indexed to a second particular result in the lookup table;
cause the adder to accumulate the first particular result and the second particular result into an output; and
send third signaling indicative of the output.

2. The memory apparatus of claim 1, wherein the lookup table comprises a dot product lookup table.

3. The memory apparatus of claim 1, wherein the trained machine learning model is a deep learning neural network machine learning model.

4. The memory apparatus of claim 1, wherein the machine learning model is stored as read-only on the non-volatile memory device.

5. The memory apparatus of claim 1, wherein the non-volatile memory device is a processor-in-memory device.

6. The memory apparatus of claim 1, wherein the non-volatile memory device is a NOT-AND (NAND) memory device.

7. The memory apparatus of claim 1, further comprising a column decoder coupled to the array to:
select only those columns associated with the first particular input in response to receipt of the first particular input; and
select only those columns associated with the second particular input in response to receipt of the second particular input.

8. A memory apparatus, comprising:
a NOT-AND (NAND) array;
an adder; and
control circuitry coupled to the NAND array and to the adder, wherein the control circuitry is configured to:
cause data comprising a lookup table to be stored in the NAND array, wherein the lookup table comprises results of dot products of weights and inputs for a trained machine learning model;
receive signaling indicative of a particular input to the machine learning model;
cause the particular input to be indexed to a particular result in the lookup table;
cause data corresponding to the particular result to be transferred to the adder;
cause the adder to add individual elements of the particular result to yield an output; and
send signaling indicative of the output.

9. The memory apparatus of claim 8, wherein the control circuitry is configured to cause the data comprising the lookup table to be stored in the NAND array such that the results of dot products of the inputs for each weight are stored in a different access line.

10. The memory apparatus of claim 8, further comprising an access line decoder coupled to the NAND array;
wherein the control circuitry is configured to cause the access line decoder to select a particular access line corresponding to a desired weight to be selected to cause the particular input to be indexed to the particular result.

11. The memory apparatus of claim 8, further comprising a column decoder coupled to the NAND array;
wherein the column decoder is configured to select only those columns associated with the particular input in response to receipt of the particular input; and
wherein the control circuitry is further configured to cause the particular input to be sent to the column decoder to cause the particular input to be indexed to a particular result in the lookup table.

12. The memory apparatus of claim 11, wherein the control circuitry is further configured to:
cause host data to be stored in the NAND array;
cause a page of the host data to be read from the NAND array in response to receipt of a request for the page of host data; and
cause the column decoder to select all columns for the request for the page of host data.

13. The memory apparatus of claim 8, wherein the NAND array of memory cells comprises an array of single-level memory cells.

14. The memory apparatus of claim 8, wherein the NAND array of memory cells comprises an array of multi-level memory cells.

15. The memory apparatus of claim 8, wherein the NAND array of memory devices comprises a plurality of lookup tables.

16. The memory apparatus of claim 8, wherein the lookup table is read-only, and values in the lookup table are constant.

17. The memory apparatus of claim 8, wherein the lookup table comprises a dot product result for a plurality of weights.

18. A method, comprising:
sensing and saving, utilizing a column decoder of a non-volatile memory device, a first input and a second input to a cache comprising a read-only, trained machine learning model (MLM);
indexing, utilizing the column decoder, the first input only to a column of a first lookup table associated with the first input in response to receipt of the first input;
indexing, utilizing the column decoder, the second input only to a column of a second lookup table associated with the second input in response to receipt of the second input,
wherein the first and the second lookup tables comprise results of dot products of weights and inputs for the trained MLM;
transferring results of the indexing of the first and the second input to an adder coupled to the non-volatile memory device;
accumulating, utilizing the column decoder and an adder, individual elements of the results; and
outputting the accumulation.

19. The method of claim 18, further comprising determining a weight dot product result for each weight layer of the MLM.

20. The method of claim 18, further comprising:
receiving the first and the second inputs as integers; and
receiving each one of the weights at the non-volatile memory device as an integer.
